(19) United States
(12) Patent Application Publication
(10) Pub. No.: US 2023/0178441 A1
(43) Pub. Date: Jun. 8, 2023

(54) ATOMIC LAYER DEPOSITED (ALD) OXIDE SEMICONDUCTORS FOR INTEGRATED CIRCUITS (ICS)

(71) Applicant: Purdue Research Foundation, West Lafayette, IN (US)

(72) Inventors: Peide Ye, West Lafayette, IN (US); Mengwei Si, West Lafayette, IN (US)

(21) Appl. No.: 17/643,214

(22) Filed: Dec. 8, 2021

(51) Int. Cl. H01L 21/8238; H01L 21/02; H01L 21/324

(52) U.S. Cl. CPC H01L 21/823821; H01L 21/0228; H01L 21/02181; H01L 21/324; H01L 29/7869

(57) ABSTRACT

Atomic layer deposited (ALD) oxide semiconductors for integrated circuits are disclosed. In one aspect, an ALD process is used to form an oxide semiconductor channel formed from Indium Oxide (In₂O₃) on a transistor formed in a back end of line (BEOL) process. In further aspects, the thickness of the In₂O₃ is controlled to a desired thickness and annealed to reduce defects. Still further aspects of the present disclosure may use this process on a fin-based field-effect transistor (FinFET).

### BACKGROUND

### I. Field of the Disclosure

The technology of the disclosure relates generally to a transistor having an oxide semiconductor channel.

### II. Background

Computing devices abound in modern society, and more particularly, mobile communication devices have become increasingly common. The prevalence of these mobile communication devices is driven in part by the many functions that are now enabled on such devices. Increased processing capabilities in such devices means that mobile communication devices have evolved from pure communication tools into sophisticated mobile entertainment centers, thus enabling enhanced user experiences. With the advent of the myriad functions available to such devices, there has been increased pressure to find ways to shrink individual circuits within the mobile devices so that more circuits and correspondingly more functions may be provided in the same amount of space in an integrated circuit (IC).

ICs commonly are formed in at least two stages, including a front end of the line (FEOL) process where the primary silicon complementary metal oxide semiconductor (CMOS) elements are formed, typically at relatively high temperatures, and a back end of line (BEOL) process where additional transistors and circuits are formed above or within metal layers above the basic silicon CMOS elements. BEOL processes are typically temperature constrained so as not to damage the underlying silicon CMOS elements. Accordingly, there is always room for improved BEOL processes.

### SUMMARY

Aspects disclosed in the detailed description include atomic layer deposited (ALD) oxide semiconductors for integrated circuits (ICs). In particular, exemplary aspects of the present disclosure contemplate using an ALD process to form an oxide semiconductor channel formed from Indium Oxide (In₂O₃) on a transistor formed in a back end of line (BEOL) process. In further aspects, the thickness of the In₂O₃ is controlled to a desired thickness and annealed to reduce defects. Still further aspects of the present disclosure may use this process on a fin-based field-effect transistor (FinFET). Use of exemplary aspects of the present disclosure may allow for a high-performance transistor with high mobility and high maximum drain current.

In this regard in one aspect, a transistor is disclosed. The transistor comprises a source. The transistor also comprises a drain. The transistor also comprises an oxide semiconductor channel having a thickness below ten nanometers (10 nm) extending between the source and the drain.

In another aspect, a method of forming a transistor is disclosed. The method comprises forming, using an atomic layer deposition process, an oxide semiconductor channel of Indium Oxide (In₂O₃) over a gate dielectric material, wherein the oxide semiconductor channel has a thickness less than 10 nm.

In another aspect, a method of forming a transistor is disclosed. The method comprises forming, using an atomic layer deposition process, an oxide semiconductor channel of In₂O₃, wherein the oxide semiconductor channel has a thickness less than 10 nm. The method also comprises forming a gate dielectric material over the oxide semiconductor channel.

### BRIEF DESCRIPTION OF THE DRAWINGS

FIG. 1 is a flowchart illustrating an exemplary back end of line (BEOL) process for forming a transistor having an oxide semiconductor channel formed through atomic layer deposition (ALD) according to the present disclosure;

FIGS. 2A-2E illustrate exemplary steps of the process of FIG. 1;

FIG. 3A illustrates a completed transistor formed according to the process of FIG. 1;

FIG. 3B illustrates an alternate fin-based transistor formed according to the process of FIG. 1;

FIGS. 4A-4C illustrate transition electron microscopy (TEM) images of a fin-based field-effect transistor (FinFET) formed according to the process of FIG. 1; and

FIGS. 5A-5I are graphs illustrating various characteristics of a transistor formed according to the process of FIG. 1; and

FIGS. 6A and 6B are graphs illustrating various characteristics of a FinFET formed according to the process of FIG. 1.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed in the detailed description include atomic layer deposited (ALD) oxide semiconductors for integrated circuits (ICs). In particular, exemplary aspects of the present disclosure contemplate using an ALD process to form an oxide semiconductor channel formed from Indium Oxide (In₂O₃) on a transistor formed in a back end of line (BEOL) process. In further aspects, the thickness of the In₂O₃ is controlled to a desired thickness and annealed to reduce defects. Still further aspects of the present disclosure may use this process on a fin-based field-effect transistor (FinFET). Use of exemplary aspects of the present disclosure may allow for a high-performance transistor with high mobility and high maximum drain current.

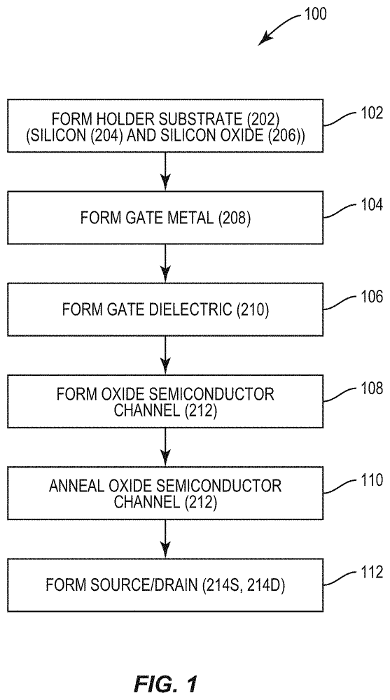

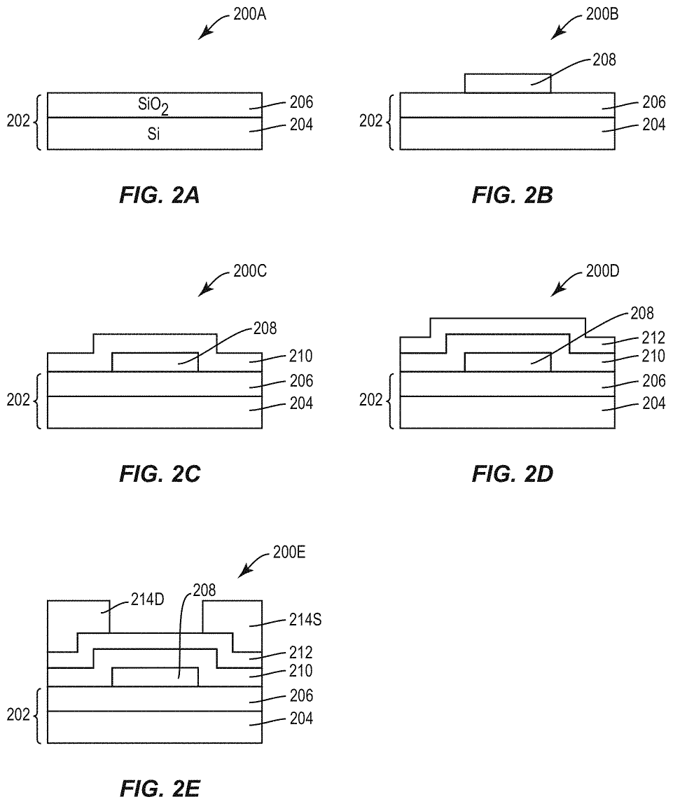

In this regard, FIG. 1 illustrates a flowchart of a process 100 for making a transistor according to exemplary aspects of the present disclosure while FIGS. 2A-2E illustrate intermediate products 200A-200E that are created as the process 100 is implemented. It should be appreciated that this process 100 is a BEOL process and generally takes place at or below 350° C. The process 100 begins by forming a holder substrate 202 (block 102, FIG. 2A) such as by forming a silicon substrate 204 with a layer of silicon oxide 206 thereover to form intermediate product 200A. It should be appreciated that this holder substrate 202 is a sacrificial layer and may be removed prior to incorporation into a complementary metal oxide semiconductor (CMOS) circuit.

The process 100 continues by forming a gate metal 208 (block 104, FIG. 2B) on the silicon oxide 206 to form intermediate product 200B. In an exemplary aspect, the gate metal 208 is Nickel (Ni) and may be between 30 and 50 nanometers (nm) and more specifically may be approximately 40 nm. Formation of the gate metal 208 may be through deposition, sputtering, or the like. As used herein, approximately means within five percent.

The process 100 continues by forming a gate dielectric 210 (block 106, FIG. 2C) over the gate metal 208 and silicon oxide 206 to form intermediate product 200C. In an exemplary aspect, the gate dielectric 210 is a high-K material such as Hafnium oxide (HfO₂) and may be between 2 and 10 nm thick, and more specifically may be approximately 5 nm. Formation of the gate dielectric 210 may be through thermal ALD, deposition, sputtering, or the like. In an alternate aspect, the gate dielectric 210 may be a ferroelectric material such as Lead Zirconate Titanate (PbZrTiO₃), Barium Titanate (BaTiO₃), or Lead Titanate (PbTiO₃). Use of ferroelectric materials may be of use in memory elements.

The process 100 continues by forming an oxide semiconductor channel 212 (block 108, FIG. 2D) over the gate dielectric 210 to form intermediate product 200D. In an exemplary aspect, the oxide semiconductor channel 212 is In₂O₃ and may have a thickness less than 10 nm, and more specifically may be less than 3 nm, and more specifically may be between approximately 2.2 and 2.5 nm. In an exemplary aspect, the oxide semiconductor channel 212 is formed through thermal ALD. Other forms of ALD may also be used, but thermal ALD may still operate below 400° C. and is adequate without the complexity of other ALD techniques (e.g., plasma ALD, photo assist ALD, metal ALD, or catalytic ALD).

The process 100 continues by annealing the oxide semiconductor channel 212 (block 110). Annealing may, for example, take place between approximately 300° C. and 350° C. and may use Oxygen (O₂), Nitrogen (N₂), or a forming gas such as 96% N₂/4% Hydrogen (H₂). Annealing helps remove low temperature defects.

The process 100 continues by forming a source 214S and drain 214D (block 112, FIG. 2E) over the oxide semiconductor channel 212 to form product 200E. In an exemplary aspect, the source 214S and the drain 214D are also Ni. Note that Ni may be replaced with other metals such as Tungsten (W) or the like as is well understood.

While the process 100 and associated FIGS. 2A-2E contemplate that the gate be formed beneath or below the oxide semiconductor channel 212, it should be appreciated that such is not strictly required. As an alternative, not shown aspect, the oxide semiconductor channel 212 may be formed on the silicon oxide 206, then the gate dielectric 210 may be formed followed by forming the gate metal 208 such that the gate is placed on top of the oxide semiconductor channel 212.

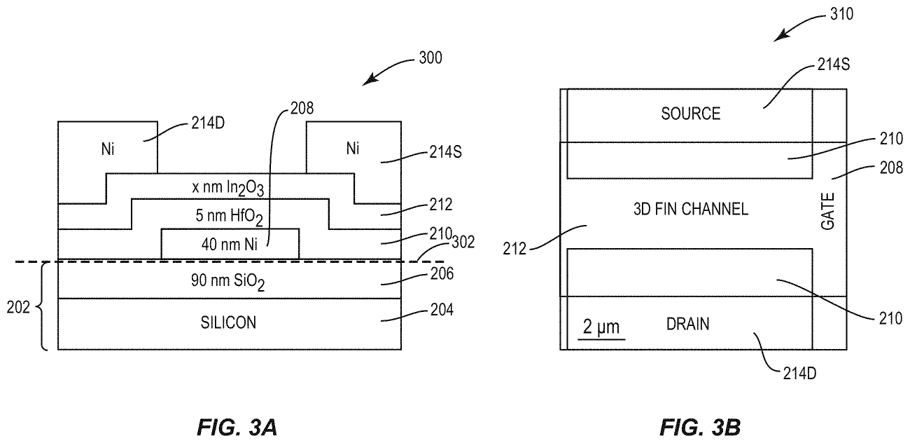

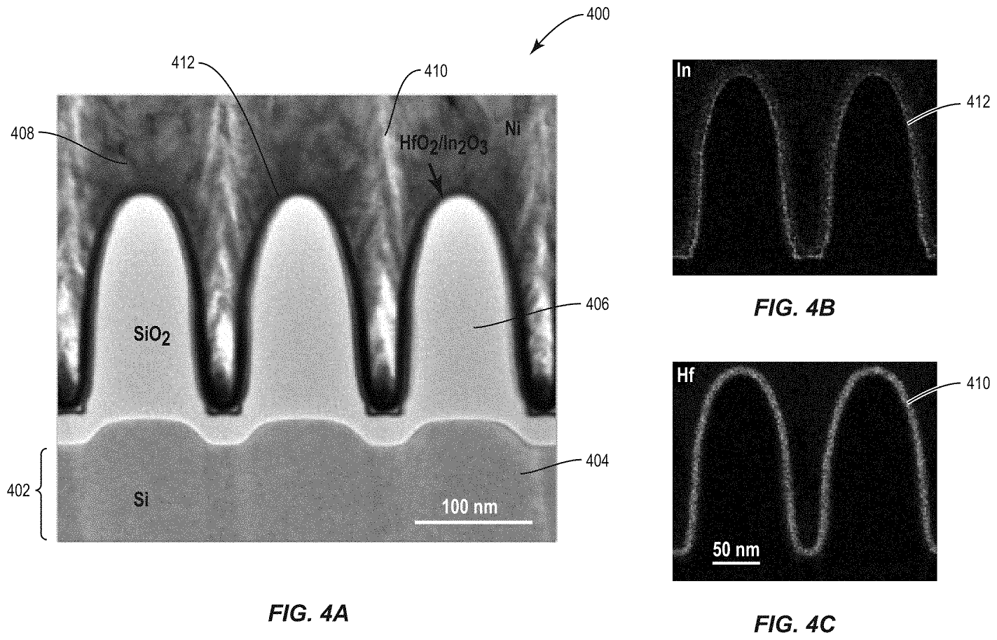

A transistor 300 is illustrated in FIG. 3A, made according to the process 100 and using the exemplary dimensional values described above. As seen by line 302, the substrate holder 202 may be removed before integration with a CMOS FEOL device. Exemplary dimensions and materials in accordance with those described above are also labeled in FIG. 3A.

While a traditional transistor is contemplated, it should be appreciated that the present disclosure is not so limited and a finFET transistor may also be made through the process 100 as illustrated by finFET 310 in FIG. 3B. In the finFET 310, the oxide semiconductor channel 212 is formed into a three-dimensional (3D) fin as is common for finFETs.

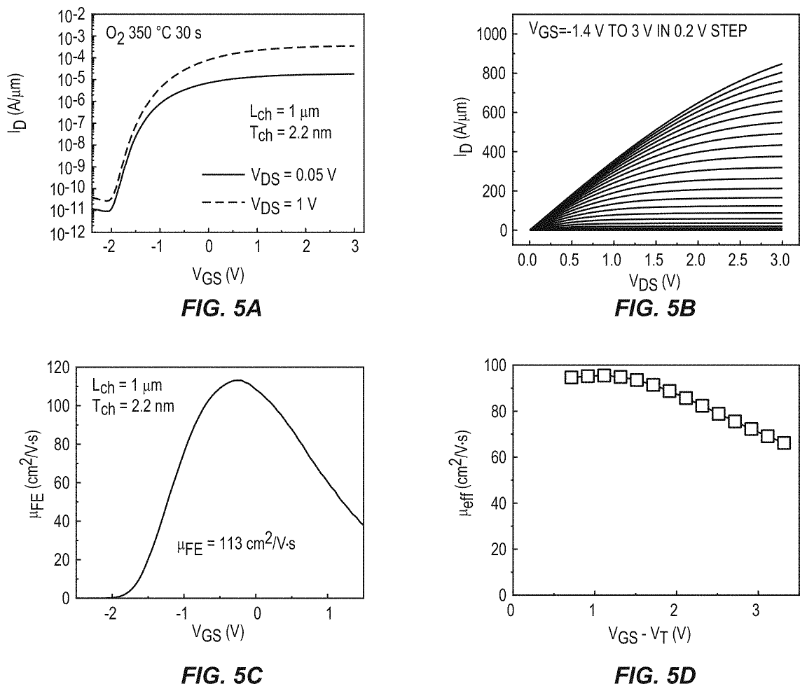

Alternate views of a finFET 400 are provided with reference to FIGS. 4A-4C. In particular, the finFET 400 includes a holder substrate 402 formed from a silicon substrate 404 with fins 406 made from silicon oxide (SiO₂). In an exemplary aspect, the fins 406 have a fin height of approximately 180 nm and a fin pitch of 130 nm. A gate material 408 may surround the fins 406 with a dielectric layer 410 and an oxide semiconductor channel 412 between the fins 406 and the gate material 408. The In₂O₃ layer of the oxide semiconductor channel 412 is highlighted in FIG. 4B and the dielectric layer 410 is highlighted in FIG. 4C.

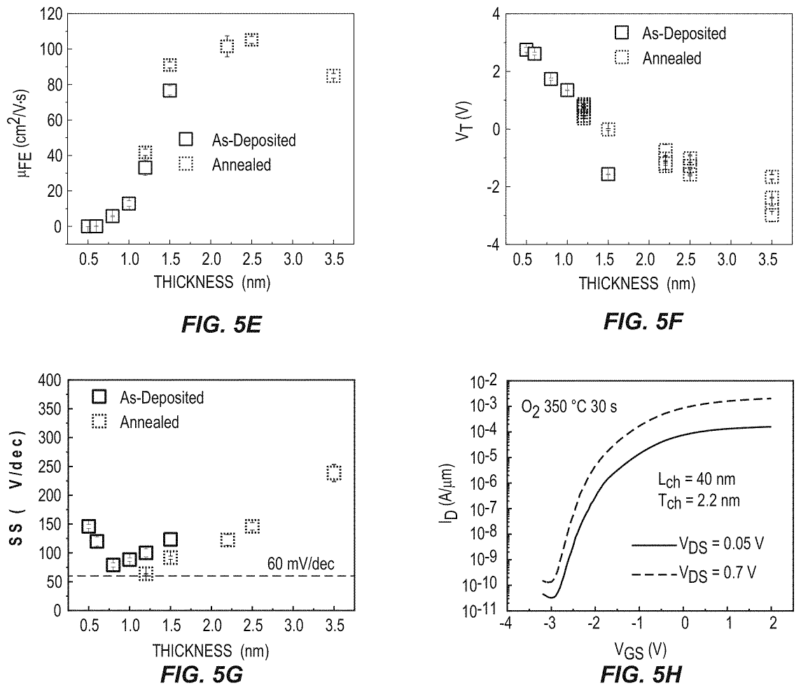

FIGS. 5A-5I illustrate various characteristics of a transistor made according to the process 100. In particular, FIG. 5A illustrates the drain current (I_{D}) versus drain-source voltage (V_{DS}) of a planar transistor (e.g., transistor 200E, 300) with a channel length of one micrometer (1 μm) and a channel thickness of 2.2 nm with O₂ annealing for two different drain-source voltages (V_{DS}). Similarly, FIG. 5B illustrates the drain current (I_{D}) versus gate-source voltage (V_{DS}) of a planar transistor (e.g., transistor 200E, 300) with a channel length of 1 μm and a channel thickness of 2.2 nm with O₂ annealing for a variety of different gate-source voltages (V_{GS}).

FIG. 5C illustrates μ_{FE} versus gate-source voltage (V_{GS}) extracted from the maximum gₘ at a drain-source voltage (V_{DS}) of 0.05 V. FIG. 5D illustrates μ_{eff} versus gate-source voltage (V_{GS}) extracted from the maximum g_{d}. The consistency of μ_{FE} and μ_{eff} is readily apparent. FIG. 5E illustrates μ_{FE} versus channel thickness extracted from as-deposited devices with optimized annealing. This shows the benefits of the channel thickness being between the 2.0 to 2.5 nm range.

FIG. 5F illustrates V_{T} versus channel thickness (T_{ch}) extracted from as-deposited devices with different annealing conditions. Again, the advantages of T_{ch} being between 2.0 and 2.5 nm is illustrated. FIG. 5G illustrates SS versus T_{ch} with optimized annealing conditions.

FIG. 5H illustrates drain current (I_{D}) versus gate-source voltage (V_{GS}) with a channel length of 40 nm and T_{ch} of 2.2 nm with O₂ annealing at 350° C. for a FET at two drain-source voltages (V_{DS}). Similarly, FIG. 5I illustrates drain current (I_{D}) versus drain-source voltage (V_{DS}) with a channel length of 40 nm and T_{ch} of 2.2 nm with O₂ annealing at 350° C. for a FET at various gate-source voltages (V_{GS}).

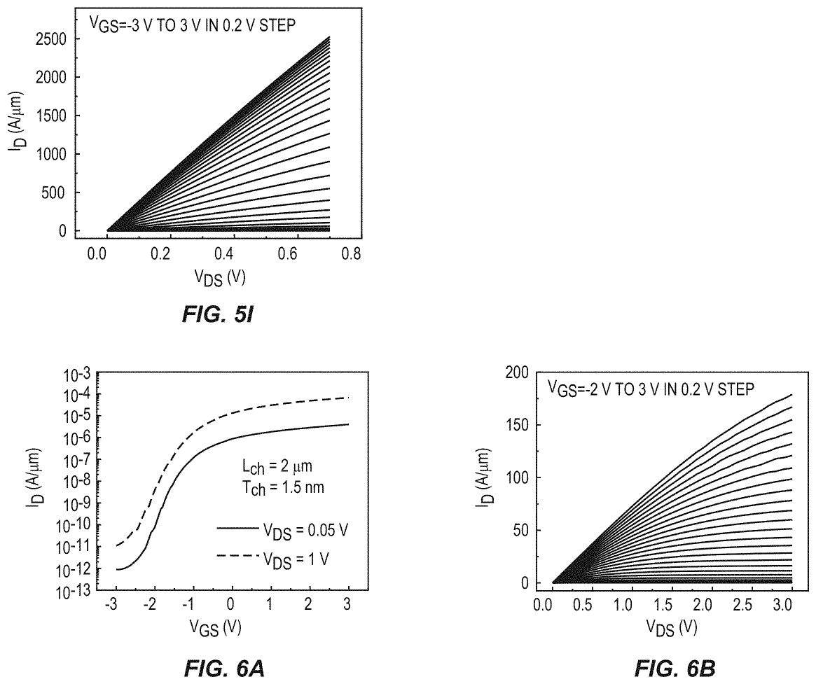

FIG. 6A illustrates drain current (ID) versus gate-source voltage (V_{GS}) with a channel length of 2 μm and T_{ch} of 1.5 nm for a finFET at two drain-source voltages (V_{DS}). Similarly, FIG. 6B illustrates drain current (ID) versus drain-source voltage (V_{DS}) with a channel length of 2 μm and T_{ch} of 1.5 nm for a finFET at various different gate-source voltages (V_{GS}).

Those of skill in the art will further appreciate that the various illustrative circuits described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

What is claimed is:

1. A transistor comprising:
a source;
a drain; and
an oxide semiconductor channel having a thickness below ten nanometers (10 nm) extending between the source and the drain.

2. The transistor of claim 1, wherein the oxide semiconductor channel comprises Indium Oxide (In₂O₃).

3. The transistor of claim 1, further comprising a gate and a high-k dielectric material, the high-k dielectric material positioned between the gate and the oxide semiconductor channel.

4. The transistor of claim 3, wherein the high-k dielectric material comprises Hafnium Oxide (HfO₂).

5. The transistor of claim 1, further comprising a gate and a ferroelectric material, the ferroelectric material positioned between the gate and the oxide semiconductor channel.

6. The transistor of claim 1, wherein the oxide semiconductor channel has a thickness between approximately 1 and 5 nm.

7. The transistor of claim 1, wherein the oxide semiconductor channel has a thickness between approximately 2.2 and 2.5 nm.

8. The transistor of claim 1, wherein the oxide semiconductor channel is annealed.

9. The transistor of claim 1 integrated into an integrated circuit (IC).

10. A method of forming a transistor, comprising:
forming, using an atomic layer deposition process, an oxide semiconductor channel of Indium Oxide (In₂O₃) over a gate dielectric material, wherein the oxide semiconductor channel has a thickness less than ten nanometers (10 nm).

11. The method of claim 10, further comprising:
forming a gate; and
forming the gate dielectric material over the gate.

12. The method of claim 11, wherein forming the gate comprises forming a fin-shaped gate.

13. The method of claim 10, wherein the oxide semiconductor channel has a thickness less than 3 nm.

14. The method of claim 10, wherein the oxide semiconductor channel has a thickness between 2.2 and 2.5 nm.

15. The method of claim 10, further comprising forming a source and a drain on the oxide semiconductor channel.

16. The method of claim 10, further comprising annealing the oxide semiconductor channel.

17. The method of claim 16, wherein annealing comprises annealing in an Oxygen (O₂), Nitrogen (N₂), or forming gas.

18. The method of claim 16, wherein annealing comprises annealing for thirty seconds at a temperature between 250° C. to 350° C.

19. A method of forming a transistor, comprising:
forming, using an atomic layer deposition process, an oxide semiconductor channel of Indium Oxide (In₂O₃), wherein the oxide semiconductor channel has a thickness less than ten nanometers (10 nm); and
forming a gate dielectric material over the oxide semiconductor channel.

20. The method of claim 19, further comprising forming a gate over the gate dielectric material.
